(19) United States
(12) Patent Application Publication
(10) Pub. No.: US 2006/0233003 A1
(43) Pub. Date: Oct. 19, 2006

(54) Matrix display device

(75) Inventors: Hirofumi Iwanaga, Tokyo (JP); Shigeaki Noumi, Tokyo (JP); Hiroshi Ueda, Kumamoto (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Chiyoda-ku (JP)

(21) Appl. No.: 11/360,675

(22) Filed: Feb. 24, 2006

(30) Foreign Application Priority Data
Apr. 5, 2005 (JP) 2005-108686

(51) Int. Cl. G11C 19/08

(52) U.S. Cl. 365/1

(57) ABSTRACT

A matrix display device includes an array substrate which controls switching elements connected to pixel electrodes surrounded by gate and source lines by a select signal, and supplies a video signal to the pixel electrodes, a unit that switches between a first and a second scan modes according to an input signal, flexible substrates provided with a gate driver for supplying a signal to the gate line and electrode terminals, and gate control signal lines formed on the array substrate and connecting together corresponding electrode terminals on adjacent flexible substrates. The electrode terminals are formed along single edges of the flexible substrates on a side of the array substrate. The gate control signal lines are formed on an opposite side of the gate driver. The gate control signal line includes first and second gate scan start signal lines which become active during first and second scan modes, respectively.

### BACKGROUND OF THE INVENTION

1. Field of the Invention

The present invention relates to a matrix display device, and more particularly, to a matrix display device which has the function of enabling a reverse-scan function in accordance with an electrical signal input to the display device and which is arranged to cause a signal line to a gate driver or a source driver to run through a wire formed in an insulating substrate.

2. Description of the Related Art

Some matrix display devices; e.g., liquid-crystal display devices, have a so-called reverse scan display mode in order to enhance the degree of freedom of installation direction (see, e.g., JP-A-6-160803). In the reverse scan display mode, according to convenient installation of the display device, an image can be displayed while being turned upside down by means of vertically reversing a sequence of line scan, or an image can be displayed while being turned laterally by means of laterally reversing a sequence of acquisition of an image signal.

Meanwhile, effecting the reverse scan display mode requires the function of vertically reversing the sequence of application of a scan signal to a gate line or the function of laterally reversing the sequence of acquisition of a video signal by a source driver. A driver having a configuration which enables switching between the functions by means of an electrical signal has already been known (see, e.g., JP-A-2000-235376 for a gate driver).

In terms of chip size, a restriction is imposed on the number of outputs of the gate driver. In general, a plurality of gate drivers are used for one liquid-crystal display device. In another known configuration, a buffer for a gate control signal which controls the gate driver is provided in each of the gate drivers, and the plurality of gate drivers are connected in the form of a cascade. Further, a line for the gate control signal is routed so as to pass through a glass substrate, thereby omitting a gate wiring board (see, e.g., JP-A-2003-50402).

A means for switching the vertical scan direction of the related-art liquid-crystal display device is usually embodied by providing a timing controller, which supplies the gate control signal to the gate driver, with a mechanical switch; and causing the timing controller to read an ON/OFF state of the switch to thus set an output of the timing controller to a predetermined state.

In this case, an installation worker manually sets the ON/OFF of the switch according to requirements for installation of the display device, which is troublesome and poses a potential risk of erroneous setting leading to an erroneous display.

In relation to a gate scan start signal, which represents a timing when scanning of a first gate line is to be started, among the gate control signals to the gate drivers, there is a necessity for switching the transmission direction of the signal in association with switching of a vertical scan direction.

Two gate scan start signals, which are output from the timing generator and represent an ordinary scan mode, or a first scan mode, and a reverse scan mode, or a second scan mode, are connected to a gate driver which activates the uppermost gate line and another driver which activates the lowermost gate line, respectively. Cascaded drivers between the uppermost gate driver and the lowermost gate driver must also be routed. Particularly, a configuration from which the gate wiring board is omitted suffers a problem of an increase in the number of connection terminals provided between the gate drivers and a flexible substrate.

### SUMMARY OF THE INVENTION

The invention provides a display device which negates a necessity for setting a mechanical switch through operator action and which enables switching of a scan direction in accordance with an electrical signal input to the matrix display device. Further, the invention provids a matrix display device which realizes a reduction in the number of connection terminals provided between the gate drivers and the flexible substrate by means of routing the gate start signal lines over a flexible substrate on which the gate drivers are mounted.

According to an aspect of the present invention, a matrix display device includes an array substrate which controls and brings into electrical conduction a plurality of switching elements connected to a plurality of pixel electrodes surrounded by a plurality of gate lines and a plurality of source lines by a select signal supplied through the gate lines and supplies a video signal supplied over the source lines to the pixel electrodes by way of the switching elements, a unit that switches between a first scan mode and a second scan mode in accordance with an electrical signal input to the matrix display device, a plurality of flexible substrates provided with a gate driver for supplying a signal to the gate line and a plurality of electrode terminals connected to the gate driver, and a plurality of gate control signal lines which are formed on the array substrate and connect together corresponding electrode terminals on adjacent flexible substrates. The plurality of electrode terminals are formed along single edges of the flexible substrates on a side of the array substrate when viewed from the gate driver. The plurality of gate control signal lines are formed on an opposite side of the gate driver when viewed from the single edges of the flexible substrates. The gate control signal line includes a first gate scan start signal line which becomes active during the first scan mode and a second gate scan start signal line which becomes active during the second scan mode.

According to the matrix display device of the invention, there is no necessity for setting a scan direction changeover switch through a human act, and a reverse scan function can be realized in accordance with an electrical signal input to the matrix display device. Further, the number of connection terminals provided between the gate drivers and the flexible substrates can be suppressed.

### BRIEF DESCRIPTION OF THE DRAWINGS

FIG. 1 is a block diagram of a liquid-crystal display device according to a first embodiment of the invention;

FIG. 2 is a circuit diagram of a gate drive circuit of the first embodiment of the invention;

FIG. 3 is a detailed view of the neighborhood of a gate driver of the first embodiment of the invention;

FIG. 4 is a timing chart of a gate scan achieved during forward scan in the first embodiment of the invention;

FIG. 5 is a timing chart of a gate scan achieved during reverse scan in the first embodiment of the invention;

FIG. 6 is a block diagram of a liquid-crystal display device according to a second embodiment of the invention; and

FIG. 7 is a detailed view of the neighborhood of a gate driver of the second embodiment of the invention.

### DETAILED DESCRIPTION OF THE INVENTION

### First Embodiment

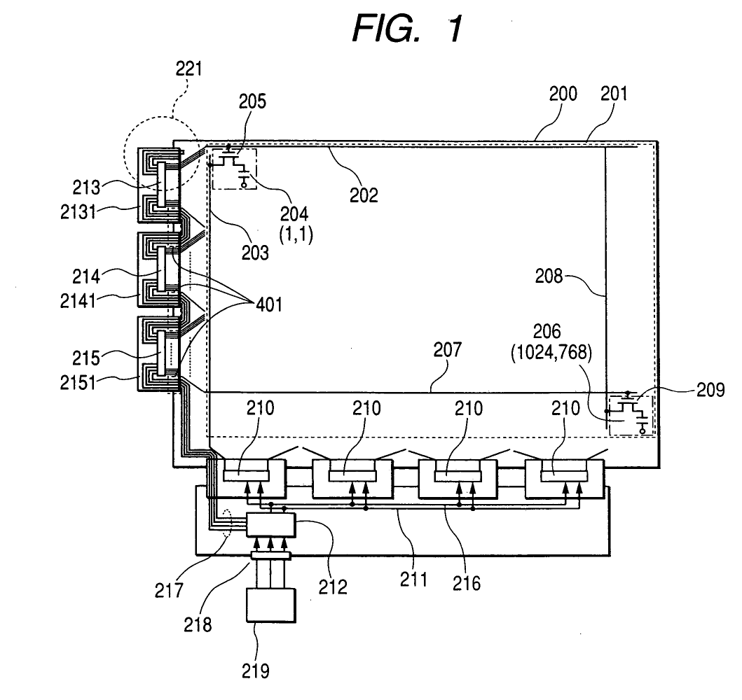

FIG. 1 is a block diagram showing a liquid-crystal display device according to a first embodiment for implementing the invention. A video signal, horizontal and vertical synchronizing signals, and a reverse scan ON/OFF signal are input from an external controller 219 to the liquid-crystal display device by way of a connector 218. The reverse scan ON/OFF signal is for controlling whether the liquid-crystal display device is brought into an ordinary scan display mode; that is, a first scan mode, or the reverse scan mode; that is, a second scan mode. In the drawing, reference numeral 200 designates a TFT array substrate which is a principal constituent element of a liquid-crystal display device having a resolution of an XGA (Extended Graphics Array: 1024 columns×768 lines). In a display area 201 on a glass substrate indicated by a broken line, 768 scan lines and 1024 signal lines, which intersect with each other at right angles, are formed into the pattern of a matrix. TFTs used for activating liquid-crystal are formed in the corners of a pixel area enclosed by the scan lines and the signal lines. A liquid-crystal material is sandwiched between the TFT array substrate and an opposing substrate formed by placing a translucent conductive film (e.g., an ITO film) on a glass substrate, with a predetermined interval therebetween, to thus form a liquid-crystal panel. Formed along edges of the TFT array substrate are terminal sections to which are connected gate drivers for driving the scan lines (hereinafter called “scan line drive gate drivers”) and source drivers for driving the signal lines (hereinafter called “signal line drive source drivers”).

In FIG. 1, a pixel 204 is driven by a TFT 205 which is connected to a first gate line 202 in the topmost line and a first source line 203 in the leftmost column. Provided that the address of the position of the TFT 205 is defined as (1, 1), the address of a pixel 206 in the lowest line and in the rightmost column can be defined as (1024, 768). The pixel 206 is driven by a TFT 209 connected to a 768th gate line 207 and a 1024th source line 208. Unillustrated TFTs, which are connected to a plurality of other, unillustrated signal lines and a plurality of other, unillustrated scan lines, are formed at intersections of these signal lines and the scan lines, and drive corresponding pixels, to thus display an image.

The 1024 source lines are connected to outputs of four source drivers 210, each of which has 256 output terminals, in a one-to-one correspondence by way of a flexible substrate. The source drivers 210 enable an input of a video signal 211, which is used for displaying a video, from a timing controller 212. As illustrated, the video signal 211 is routed to the four source drivers 210 in parallel. A reverse scan signal 216 (hereinafter referred to as a “REV signal”) is output from the timing controller 212 and input to the source drivers 210 in parallel.

In the meantime, the 768 gate lines are connected to outputs of three gate drivers 213, 214, and 215, each of which has 256 outputs, by way of the flexible substrates in a one-to-one correspondence. The gate drivers 213, 214, and 215 are chips which are identical with each other in terms of the layout of output pins and an internal configuration. Flexible substrates 2131, 2141, and 2151, which carry the gate drivers 213, 214, and 215, are also identical with each other in terms of a wiring pattern and an outer dimension.

A gate control signal 217, which is to be output from the timing controller 212 to the gate drivers 215, 214, and 213, is connected to the gate driver 215 by way of the flexible substrate of the leftmost source driver 210, the lower-left corner of the TFT array substrate 200, and the flexible substrate 2151. As illustrated, the gate control signal 217 is connected in the form of a cascade among the gate drivers 215, 214, and 213, and is routed up to the topmost portion of the terminal section of the TFT array substrate 200 by way of the flexible substrates 2151, 2141, 2131, a plurality of electrode terminals 401 formed on the flexible substrates, and the lines formed on the TFT array substrate 200.

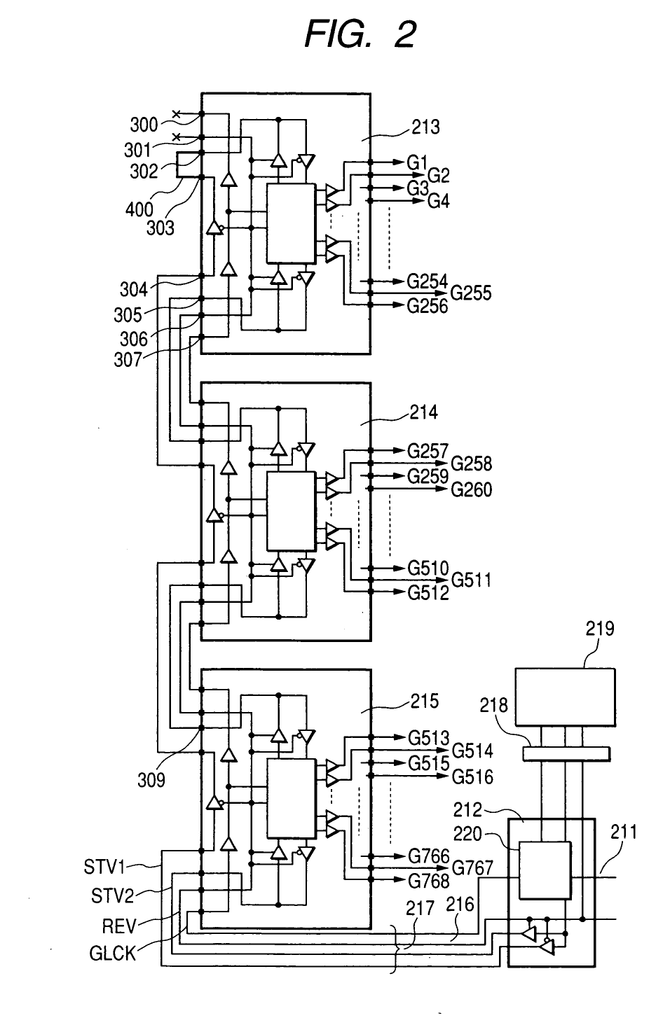

By reference to the schematic diagram of the gate drive circuit shown in FIG. 2, the internal configurations of the gate drivers 213, 214, and 215, and the cascade connection among the gate drivers 215, 214, and 213 with respect to the gate control signals 217, such as an REV signal, a gate clock signal (hereinafter called a “GCLK signal”), and a forward gate scan start signal; that is, a first gate scan start signal (hereinafter called an “STV1 signal”) will now be described. In the drawing, the REV signal output from the external controller 219 is input to the source driver 210, and passes through the cascade connection across the gate drivers 213, 214, and 215 and is input to a terminal 307 of the gate driver 213. Similarly, the horizontal and vertical signals output from the external controller 219 are separated by a signal processing circuit 220 in the timing controller 212, to thus generate the GCLK signal and the gate scan start signal. When the REV signal is LOW; that is, when reverse scan is inactive, the STV1 signal becomes active and is output from the timing controller 212. The STV1 signal passes through the cascade connection across the gate drivers 215, 214, and 213 and is input to a terminal 304 of the gate driver 213. Subsequently, the STV1 signal is output from a terminal 303 by way of a buffer in the gate driver 213. Then, the signal is input to a terminal 302 of the gate driver 213 by way of a wire-bound section 400 formed on the TFT array substrate.

The shape of the wire-bound section 400 is shown in FIG. 3 as a detailed view of a terminal section 221 of the gate driver 213. In the drawing, rectangular connection terminals for the line of the STV1 signal, the line of the STV2 signal, the line of the REV signal, the line of the GCLK signal, the line of the gate control output signal G1, the line of the gate control output G2 signal, and lines of gate control output signals G3 to G256 (not shown), all of which are laid on the flexible substrate 2131, are formed on the TFT glass substrate 200. The connection terminals are connected to counterpart rectangular connection terminals, which correspond to the connection terminals, by way of electrical-and-mechanical connection, such as an ACF. The wire-bound section 400 is formed from at least one conductive material among materials used for forming the connection terminals on the TFT glass substrate 200, and connects together the rectangular connection terminal sections. In consideration of a heat dissipation characteristic and uniformity of the surface, which are achieved when the connection terminal sections are connected by means of the ACF, the lines are temporarily drawn from the rectangular connection sections and then formed into a C-shaped or U-shaped pattern.

Similarly, the GCLK signal generated by the signal processing circuit 220 passes through the cascade connection across the gate drivers 215, 214, and 213 and is input to the terminal 307 of the gate driver 213.

Now, as is evident from the internal structures, the gate drivers 213, 214, and 215 each have a bi-directional shift register whose shifting direction is switched by the REV signal input from a terminal 306. Further, the gate driver 213 has gate control outputs G1 to G256 having output buffers connected to the shift register; the gate driver 214 has gate control outputs G257 to G512 having output buffers connected to the shift register; and the gate driver 215 has gate control outputs G513 to G768. As mentioned previously, the gate control outputs are connected to the gate lines in the display area 201 in a one-to-one correspondence.

As mentioned previously, when the REV signal is LOW, the STV1 signal input from the terminal 302 is effective as a gate scan start signal, as is obvious from the internal structure of the gate driver 213. A gate scan signal is applied from the gate control outputs G1 to G3 in ascending sequence of G1, G2, and G3.

Operation performed when the REV signal is LOW will now be described. First, the source driver 210 holds, in sequence from the left and through sample-holding, the video signal 211 output from the timing controller 212 at a timing at which the video signal is synchronized with a predetermined clock signal, as a video signal voltage assigned to the source lines 203 to 208. The source driver 210 applies in unison the thus-sample-held voltages to the source lines at a predetermined output timing.

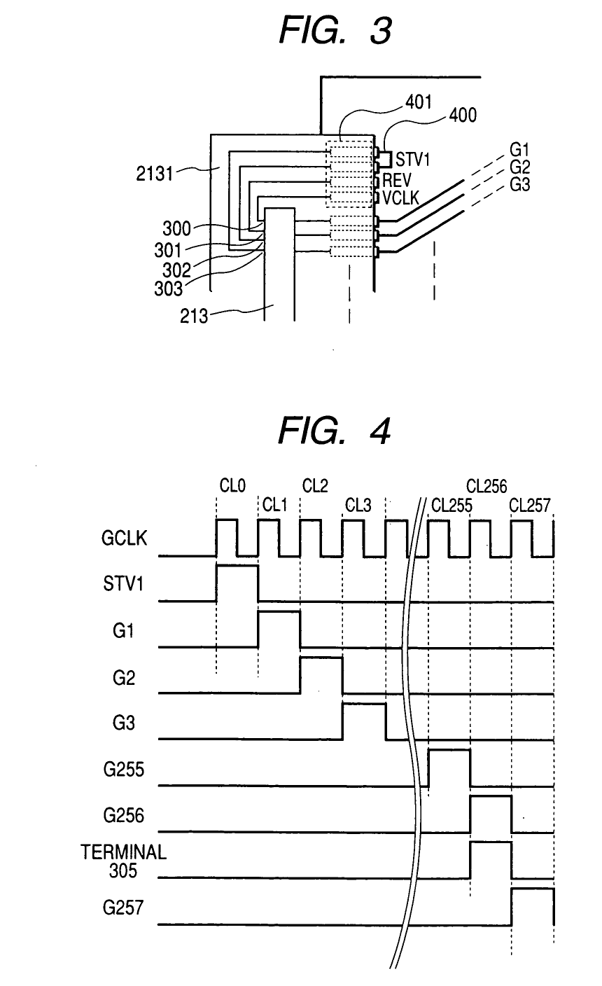

A timing relationship among the STV1 signal, the GCLK signal, and the gate control outputs G1 to G768 will now be described by reference to FIG. 4. In FIG. 4, the STV1 signal is HIGH at a CL0 cycle, and the high level is read by the bi-directional shift register. In the next cycle CL1, the HIGH level of the signal is output at the timing of the waveform indicated by the gate control output G1 in FIG. 4 in synchronism with a rise of the GCLK signal, whereupon scanning of the gate line 202 is initiated. Thus, the TFT connected to the gate line 202 is turned on. Subsequently, the G1 signal becomes LOW in the subsequent CL2 cycle, and scanning of the gate line 202 is completed. The HIGH signal is sequentially shifted by the bi-directional shift register in CL2 and CL3 cycles in the same manner. As in the case of a waveform shown in FIG. 4, a HIGH-level signal is sequentially applied to the gate control outputs G2, G3 in synchronism with the GCLK signal. When the GCLK signal has achieved a CL 256 cycle, a HIGH signal is applied to a G256 terminal, and a HIGH signal is concurrently output from the terminal 305. This signal is input to the bi-directional shift register of the gate driver 214. This signal corresponds to the STV1 signal of the gate driver 214. When the GLCK signal has achieved a CL257 cycle (not shown), a HIGH-level signal is output from a G257 terminal of the gate driver 214. In subsequent operation, shifting operation of the bidirectional shift registers in the respective gate drivers 214 and 215 and application of a HIGH-level signal to G258 to G768 terminals are similarly repeated until the gate clock signal GCLK achieves a CL768 cycle. Thus, scanning of gate lines up to the gate line 207 within the display area 201 is sequentially performed.

As mentioned above, when the REV signal is LOW, the gate terminals are sequentially brought to HIGH in a forward direction (a downward direction in FIG. 1) from the gate control output G1 of the gate driver 213 in each horizontal cycle. Accordingly, horizontal scanning is performed downwardly from the pixel 204; that is, an address (1, 1), in FIG. 1.

When reverse scan is active; that is, when the REV signal is in a HIGH level, the reverse gate scan start signal in FIG. 2; that is, a second gate scan start signal (hereinafter called an “STV2 signal”) becomes active, and the STV2 signal is output from the timing controller 212. After having been input to the gate driver 215, the STV2 signal passes through the cascade connection across the gate drivers 215, 214, and 213. Connection of the other signals is the same as that described in connection with the case where reverse scan is inactive.

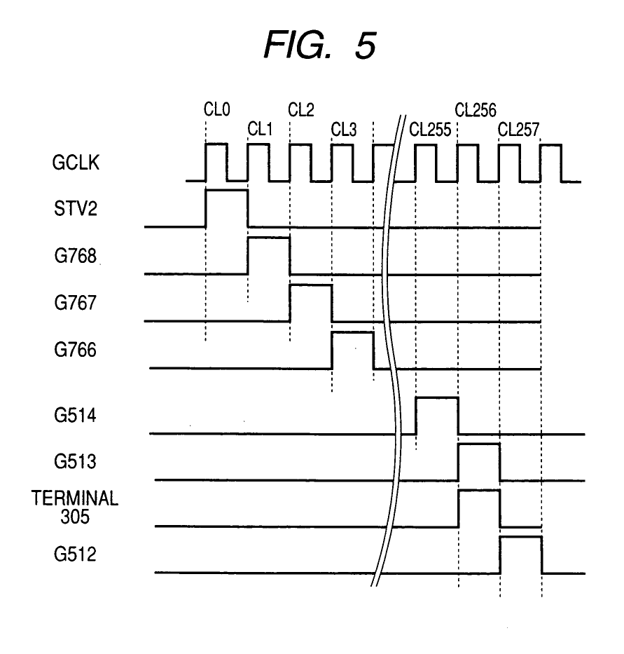

As mentioned previously, each of the gate drivers 213, 214, and 215 has the bi-directional shift register whose shifting direction is switched by the REV signal. Hence, when the REV signal is in a HIGH level, the STV2 signal, which has been input from a terminal 308, is active as a gate scan start signal. The gate scan signal is applied from the gate control outputs G768 to G766 in descending sequence of G768, G767, and G766. FIG. 5 shows timings at which the gate scan signal is applied. In FIG. 5, the HIGH level of the STV2 signal is read by the bi-directional shift register at the CL0 cycle. In synchronism with a rise of the GCLK signal in the next CL1 cycle, a HIGH-level signal is output at the timing of a waveform of the gate output terminal G768 in FIG. 4. Similarly, this HIGH-level signal is sequentially shifted by the bi-directional shift register in the cycles CL2, CL3. As in the case of the waveform shown in FIG. 5, the HIGH signal is sequentially applied to terminals G767, G766 in synchronism with the GCLK signal. Subsequently, when the GCLK signal has achieved the CL256 (not shown) cycle, a HIGH-level signal is applied to the gate control output terminal G513, and a HIGH-level signal is concurrently output from the terminal 309. This signal is input to the bi-directional shift register of the gate driver 214. This signal corresponds to the STV2 signal of the gate driver 214. Next, when the GLCK signal has achieved a CL257 cycle, a HIGH signal is output from the G512 terminal of the gate driver 214. In subsequent operation, shifting operation of the bi-directional shift registers in the respective gate drivers 214 and 213 and application of a HIGH signal to the gate control outputs G511 to G1 are similarly repeated until the gate clock signal GCLK achieves the CL768 cycle. Thus, scanning of gate lines up to the gate line 1 within the display area 201 is sequentially performed.

As mentioned previously, when the REV signal is in the HIGH level, the gate terminals are sequentially brought into a high level in a reverse direction (upward in FIG. 1) from the gate control output terminal G768 of the gate driver 215 in each horizontal cycle. Therefore, horizontal scanning is performed upwardly from the pixel 206; that is, an address (1024, 768) in FIG. 1. Namely, reverse-scan display in the vertical direction is performed.

In the reverse-scan display state, the REV signal output from the timing controller 212 enters a HIGH level. In the reverse of the sequence of sample-holding operation, the source driver 210 holds, through sample-holding, the video signal 211 in sequence from the right in FIG. 1 as video signal voltages assigned to the source lines 208 to 203, at timings synchronous with a predetermined clock, and applies in unison the thus-sample-held voltages to the source lines at a predetermined output timing.

As mentioned above, as a result of the reverse scan signal 216 input from the external controller 219; namely, the REV signal, being input to the source driver 210 and the gate drivers 213, 214, and 215, the reverse scan function can be readily switched between ON and OFF in accordance with the HIGH-level or LOW-level electrical signal from the external device. In addition, the reverse scan signal 216 is separated within the timing controller 212, to thus output the STV1 signal and the STV2 signal. Further, the terminals 303 and 302 of the gate driver 213, which is most remote from the timing controller 212, are connected at the wire-bound section 400 within the TFT glass substrate. Therefore, the gate scan start signal can be transmitted to the predetermined gate driver regardless of whether the reverse scan signal 216 is in the LOW level or the HIGH level.

The above-described embodiment shows an example where the signal lines to the source drivers are laid on the so-called source wiring board by means of adoption of a parallel wiring method. However, cascade wiring can be realized with a bi-directional shift register function and a buffer function being provided in the source driver. Especially, when an analog signal method or a digital signal data transmission method, which enables a reduction in the number of signal lines, such as an LVDS scheme or an RSDS scheme, is adopted as the video signal transmission scheme, and when the number of lines provided between the source drivers can be reduced, the lines provided among the source drivers can be laid in the form of a cascade by way of the TFT array substrate 200 and the flexible substrate. As a result, a so-called source-substrate-less configuration can be adopted with comparative ease. Even in this case, the reverse scan signal 216 is separated within the timing controller 212, to thus output an image data shift start signal STH1 (not shown) when the reverse scan signal 216 is LOW or an image data shift start signal STH2 (not shown) when the reverse scan signal 216 is HIGH. Further, an STH2 terminal (not shown) of the source driver 213, which is most remote from the timing controller 212, is connected at the connection section within the TFT glass substrate. When the reverse scan signal 216 is in the LOW level, the image data shift start signal STH1 can be electrically transmitted to the predetermined source driver. When the reverse scan signal 216 is in the HIGH level, the image data shift start signal STH2 can be electrically transmitted to the predetermined source driver.

The present embodiment has stated a case where the resolution of the display area 201 is the XGA (1024 columns×768 lines). However, no limitations are imposed on the number of columns and lines of the display area 201. The invention can be provided similarly, so long as one or more gate drivers or source drivers are used.

### Second Embodiment

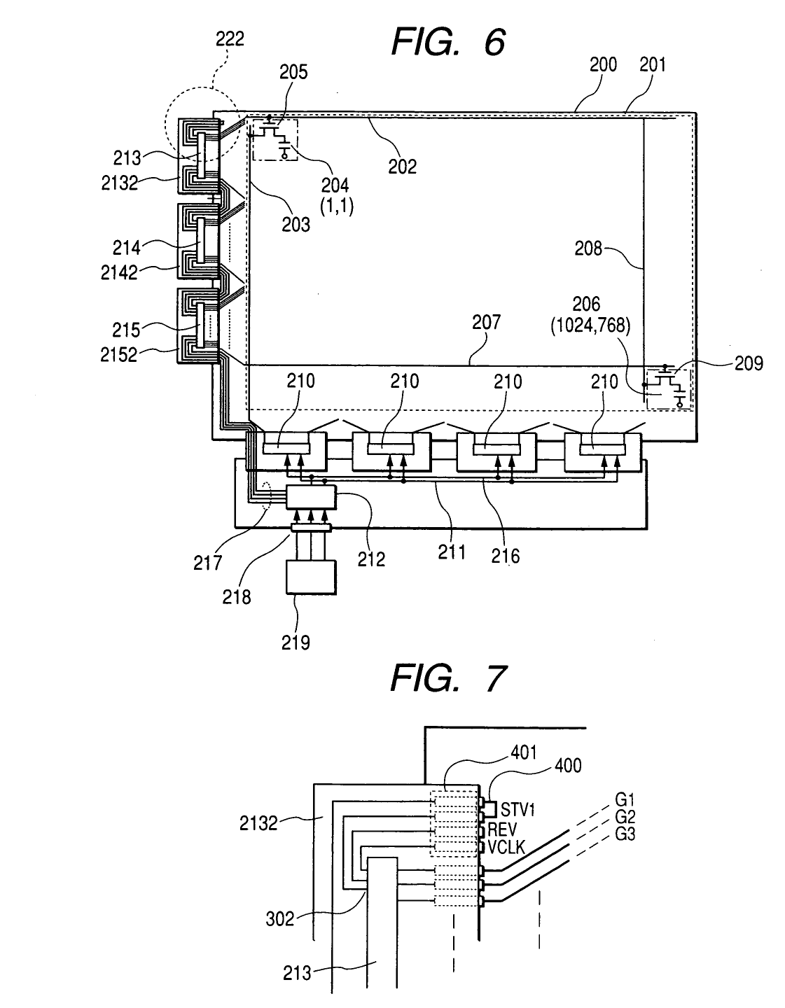

FIG. 6 is a block diagram showing a liquid-crystal display device according to a second embodiment for implementing the invention.

In the drawing, the STV1 signal output from the timing controller 212 is delivered to the wire-bound section 400 formed on the TFT array substrate 200 not by way of the buffers in the gate drivers 213, 214, and 215, but by way of flexible substrates 2132, 2142, 2143, and the TFT array substrate 200. Subsequently, as shown in FIG. 7 which is an enlarged view of a terminal section 222, the STV1 signal passes through the wire-bound section 400 and is then delivered to the terminal 302 of the gate driver 213 again byway of the flexible substrate 2132. The STV1 signal does not pass through any buffers before entering the terminal 303 of the gate driver 213. Therefore, a buffer having a capacity sufficiently large for driving a line is selected as an output buffer which drives the STV1 signal to be output from the timing controller 212.

As mentioned above, in the second embodiment, there is no necessity for laying lines for the STV1 signal, which are for buffering purposes, in the gate drivers 213, 214, and 215. The number of lines used for connecting the flexible substrates 2132, 2142, and 2152 and the gate drivers 213, 214, and 215 can be reduced, thereby enhancing reliability. Moreover, the buffer circuits and the terminal sections can be deleted from the gate drivers 213, 214, and 215, which in turn makes the chip size of the gate driver compact.

The first and second embodiments have not made specific reference to the material of the flexible substrate or a driver chip mount technology. Either a TCP method or a COF method, both of which are in wide used, can be carried out in the first and second embodiments. No specific limitations are imposed on design.

The first and second embodiments have described, as an example of a matrix display device, the example of an active matrix liquid-crystal display device which uses TFTs and has a resolution of XGA. However, the invention is not limited specifically to the resolution of XGA, and may be applicable to another resolution. Further, there is no necessity for the active-type matrix display device, and a passive matrix liquid-crystal display device may also be available. Further, any display device can be configured in the same manner as in the present embodiments, so long as the device has a plurality of matrix lines and a reverse scan function, as does an EL display, and a similar advantage can be yielded.

The liquid-crystal display device of the invention which is driven by the driving method of the first or second embodiment is configured as shown in FIG. 1. The liquid-crystal display device has the gate drivers 213, 214, 215 for supplying the gate control outputs G1 to G768 to the gate lines 202 to 207, the timing controller 212, and the line for the gate control signal 217. The liquid-crystal display device is configured to output the gate scan start signal STV1 when the reverse scan signal 216 input from the external controller 219 is LOW and to output the gate scan start signal STV2 when the reverse scan signal 216 is HIGH. Further, the liquid-crystal display device is configured such that the STV1 signal is input to the gate driver 213 by way of the wire-bound section 400 formed on the TFT glass substrate 200 when the reverse scan signal 216 is LOW.

According to the liquid-crystal display device of the invention having the above-described configuration, there can be obtained a liquid-crystal display device which can readily, electrically switch a display between a normal mode and a reverse mode, by means of solely inputting the reverse scan signal 216 to the timing controller 212 from the external controller 219.

What is claimed is:

1. A matrix display device comprising:
an array substrate which controls and brings into electrical conduction a plurality of switching elements connected to a plurality of pixel electrodes surrounded by a plurality of gate lines and a plurality of source lines by a select signal supplied through the gate lines, and supplies a video signal supplied over the source lines to the pixel electrodes by way of the switching elements;
a unit that switches between a first scan mode and a second scan mode in accordance with an electrical signal input to the matrix display device;
a plurality of flexible substrates provided with a gate driver for supplying a signal to the gate line and a plurality of electrode terminals connected to the gate driver; and
a plurality of gate control signal lines which are formed on the array substrate and connect together corresponding electrode terminals on adjacent flexible substrates, wherein
the plurality of electrode terminals are formed along single edges of the flexible substrates on a side of the array substrate when viewed from the gate driver;
the plurality of gate control signal lines are formed on an opposite side of the gate driver when viewed from the single edges of the flexible substrates; and
the gate control signal line includes a first gate scan start signal line which becomes active during the first scan mode and a second gate scan start signal line which becomes active during the second scan mode.

2. The matrix display device according to claim 1, wherein
the plurality of gate drivers are connected in the form of a cascade by the plurality of gate control signal lines output from a timing controller, and
the first or second gate scan start signal line is input to the gate driver by way of a line formed on the array substrate at a terminal section of the gate driver that is most remote when viewed from the timing controller.

3. The matrix display device according to claim 1, wherein
the first gate scan start signal and the second gate scan start signal are output as other line signals from the timing controller, and
when one of the first and second gate scan start signals is active, the other is in a high impedance state.

4. The matrix display device according to claim 1, wherein
the gate driver is mounted on the flexible substrate,
the flexible substrate is attached to a single edge of the array substrate, and
input and output of a gate control signal to the gate driver are performed by way of a line provided in an area corresponding to an interval between the adjacent flexible substrates provided along the single side of the array substrate.

5. The matrix display device according to claim 1, wherein
the first or second gate scan start signal line formed in the flexible substrate does not pass through the gate driver.
